(19) United States
(12) Patent Application Publication
(10) Pub. No.: US 2014/0176244 A1
(43) Pub. Date: Jun. 26, 2014

(54) VOLTAGE-CONTROLLED OSCILLATOR WITH HIGH LOOP GAIN

(71) Applicant: Quadlink Technology, Ltd., Zhubei City (TW)

(72) Inventor: Ching-Lung Ti, Hsinchu County (TW)

(73) Assignee: Quadlink Technology, Ltd., Zhubei City (TW)

(21) Appl. No.: 14/025,555

(22) Filed: Sep. 12, 2013

(30) Foreign Application Priority Data
Dec. 26, 2012 (TW) 101149970

(51) Int. Cl. H03L 5/02

(52) U.S. Cl. CPC H03L 5/02
USPC 331/15

(57) ABSTRACT

A voltage-controlled oscillator with high loop gain includes a first transistor, a second transistor, an inductor, a third transistor, a fourth transistor and a gain circuit. The gain circuit provides a high loop gain in the voltage-controlled oscillator, which operates at wider tuning range but with low power consumption due to capacitance value provided by transistors thereof.

### CROSS-REFERENCE TO RELATED APPLICATION

This application claims priority of application No. 101149970, filed on Dec. 26, 2012 in the Intellectual Property Office of The Republic of China.

### FIELD OF THE INVENTION

The invention relates to a voltage-controlled oscillator with high loop gain, more particularly, to a voltage-controlled oscillator having advantages of fewer electronic components, extended operating frequency range and low power consumption.

### BACKGROUND OF THE INVENTION

A voltage-controlled oscillator or VCO is an electronic oscillator whose oscillation frequency is controlled by a voltage input. The input voltage determines the instantaneous oscillation frequency. Consequently, modulating signals supplied to the control input may generate frequency modulation (FM) or phase modulation (PM).

For VCO design, inductor-capacitor (LC) tank is a preferred choice in the CMOS RFIC design because of its good phase noise and low power consumption. However LC tank involves narrow tuning range due to the resonance of inductors. The LC VCO contains an inductor and a varactor (variable capacitor), which are large in size, and thus not suitable for use as VLSI components. Several fully integrated CMOS LC-tank VCOs in various CMOS technologies have been developed. Searching for a balance between voltage supply and power consumption and the problem of phase noise are still to be solved when dealing with the design of oscillator. Moreover, the challenge in the design of a LC-tank VCO having high loop gain is the phase and amplitude increase during the starting period of the VCO with low frequency, which means that more power is consumed in order to accommodate high loop gain.

In order to solve the problem(s), the present invention introduces a LC-tank VCO with high loop gain.

### SUMMARY OF THE INVENTION

The primary objective of the present invention is to provide a voltage-controlled oscillator with high loop gain.

In order to accomplish the aforementioned objective, the voltage-controlled oscillator of the preferred embodiment of the present invention includes:
a first transistor having a source node, a gate node, and a drain node;
a second transistor having a source node, a gate node, and a drain node, the source node of the second transistor being coupled to the source node of the first transistor, the gate node of the second transistor being coupled to the drain node of the first transistor, the drain node of the second transistor being coupled to the gate node of the first transistor;
an inductor having two ends connected to the drain nodes and the gate nodes of the first transistor and the second transistor cross-coupled pair respectively;
a third transistor having a source node, a gate node, and a drain node, the gate node and the drain node of the third transistor being coupled to the ends of the inductor separately;
a fourth transistor having a source node, a gate node, and a drain node, the source node of the fourth transistor being coupled to the source node of the third transistor, the gate node of the fourth transistor being coupled to the drain node of the third transistor, the drain node of the fourth transistor being coupled to the drain node of the third transistor; and
at least one gain circuit providing a loop gain in the voltage-controlled oscillator, the gain circuit includes:
   a fifth transistor having a source node, a gate node, and a drain node, the drain node of the fifth transistor being coupled to the inductor;
   a sixth transistor having a source node, a gate node and a drain node, the source node of the sixth transistor being coupled to the source node of the fifth transistor, the gate node of the sixth transistor being coupled to the drain node of the fifth transistor, the drain node of the sixth transistor being coupled to the gate node of the fifth transistor and the inductor;
   a seventh transistor having a source node, a gate node and a drain node, the drain node of the seventh transistor being coupled to the inductor; and
   an eighth transistor having a source node, a gate node and a drain node, the source node of the eighth transistor being coupled to the source node of the seventh transistor, the gate node of the eighth transistor being coupled to the drain node of the seventh transistor, the drain node of the eighth transistor being coupled to the gate node of the seventh transistor and the inductor.

It is to be noted from the objectives of the preferred embodiment of the present invention that the voltage-controlled oscillator has gain circuit providing a loop gain. Meanwhile, the gain circuit has the parasitic and stray capacitance, which exist in the circuit of the fifth transistor, the sixth transistor, the seventh transistor, and the eighth transistor, for increasing the capacitance to the loop as switching on/off these transistors (MMOS/PMOS). Thus the circuit area of switched capacitors is smaller as well as loop gain for oscillation condition is provided.

By specific connection of the aforementioned elements (i.e., inductor and transistors) and cross-coupled pairs of the aforementioned transistors, the voltage-controlled oscillator of the present invention obtains advantages to operate in expanded operating frequency ranges, with reduced power consumption, and having higher loop gain with concise electrical circuit design.

### BRIEF DESCRIPTION OF THE DRAWINGS

FIG. 1 is a circuit schematic diagram of the voltage-controlled oscillator of embodiment of the present invention.

FIG. 2 is a schematic graph of the oscillation frequency related to control voltage in various switched capacitor and Gm of embodiment of the present invention.

FIG. 3 is still a schematic graph of the oscillation frequency related to control voltage in various switched capacitor and Gm of embodiment of the present invention.

### DETAILED DESCRIPTION OF THE INVENTION

The following description is merely exemplary in nature and is in no way intended to limit the present teachings, applications, or uses. Those of skill in the art will recognize that the following description is merely illustrative of the principles of the invention, which may be applied in various ways to provide many different alternative embodiments.

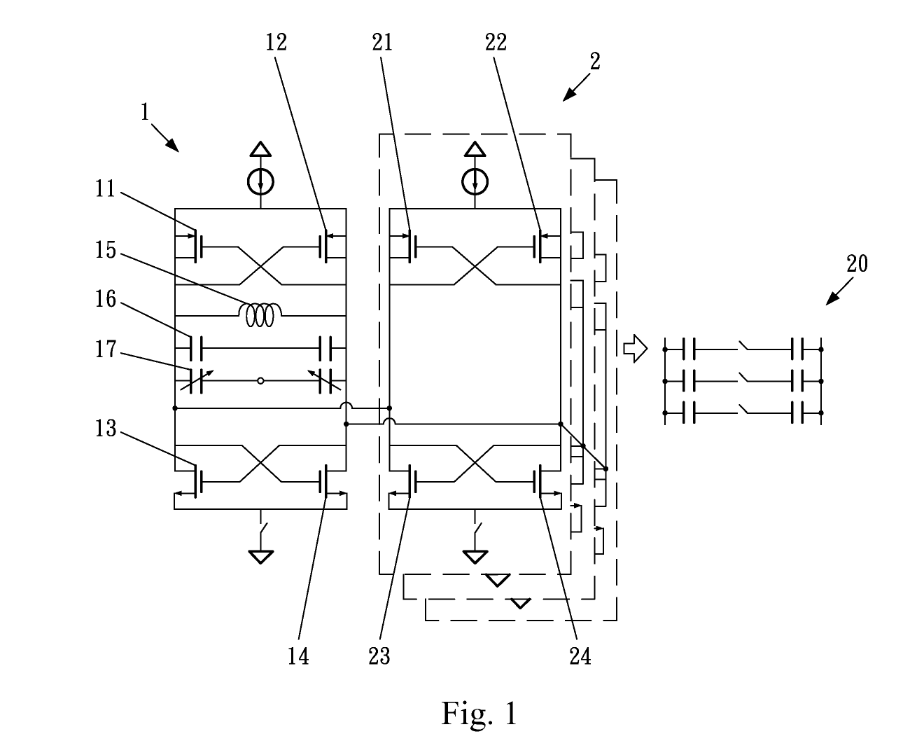

With reference to FIG. 1, a schematic circuit diagram showing a voltage-controlled oscillator according to the preferred embodiment of the present invention is shown. The voltage-controlled oscillator has a first transistor 11, a second transistor 12, an inductor 15, a third transistor 13, a fourth transistor 14 and a gain circuit 2.

The first transistor 11 has a source node, a gate node, and a drain node, and the second transistor 12 has a source node, a gate node, and a drain node. The source node of the second transistor 12 is coupled to the source node of the first transistor 11, the gate node of the second transistor 12 is coupled to the drain node of the first transistor 11, and the drain node of the second transistor 12 is coupled to the gate node of the first transistor 11.

The inductor 15 has two ends connected to the drain nodes and the gate nodes of the first transistor and the second transistor cross-coupled pair respectively. One end of the inductor 15 is coupled to the drain node of the first transistor 11 and the gate node of the second transistor 12, and the other end of the inductor 15 is coupled to the gate node of the first transistor 11 and the drain node of the second transistor 12.

The third transistor 13 has a source node, a gate node, and a drain node. The gate node and the drain node of the third transistor 13 are coupled to the ends of the inductor 15 separately.

The fourth transistor 14 has a source node, a gate node, and a drain node. The source node of the fourth transistor 14 is coupled to the source node of the third transistor 13, the gate node of the fourth transistor 14 is coupled to the drain node of the third transistor 13, and the drain node of the fourth transistor 14 is coupled to the drain node of the third transistor.

The gain circuit 2 providing a loop gain in the voltage-controlled oscillator includes a fifth transistor 21, a sixth transistor 22, a seventh transistor 23, and an eighth transistor 24.

Accordingly, the first transistor 11, the second transistor 12, the fifth transistor 21, and the sixth transistor 22 are NMOS transistors. The third transistor 13, the fourth transistor 14, the seventh transistor 23, and the eighth transistor 24 are PMOS transistors.

The fifth transistor 21 has a source node, a gate node, and a drain node, and the drain node of the fifth transistor 21 is coupled to the inductor.

The sixth transistor 22 has a source node, a gate node and a drain node. The source node of the sixth transistor 22 is coupled to the source node of the fifth transistor 21, the gate node of the sixth transistor 22 is coupled to the drain node of the fifth transistor 21, and the drain node of the sixth transistor 22 is coupled to the gate node of the fifth transistor 21 and the inductor 15.

The seventh transistor 23 has a source node, a gate node and a drain node. The drain node of the seventh transistor 23 is coupled to the inductor 15.

The eighth transistor 24 has a source node, a gate node and a drain node. The source node of the eighth transistor 24 is coupled to the source node of the seventh transistor 23, the gate node of the eighth transistor 24 is coupled to the drain node of the seventh transistor 23, and the drain node of the eighth transistor 24 is coupled to the gate node of the seventh transistor 23 and the inductor 15.

Furthermore, a capacitor 16 and a capacitor module 17 may be utilized in the VCO circuit. The capacitor 16 is a switched capacitor for coarse frequency tuning and has two electrodes coupled the ends of the inductor 15 separately.

The capacitor module 17 has two varactor diodes, whose negative electrodes are coupled with the inductor 15, and whose positive electrodes are coupled with a voltage-controlled power terminal, which is adapted for externally controllably changing the capacitance of the capacitor module 17.

Referring to FIG. 1, connections among the elements (i.e., inductors, capacitors, and transistors) of the voltage-controlled oscillator will be described more fully hereinafter.

Accordingly, a pair of cross-coupled transistors provides a positive feedback element. In the embodiment, a complementary cross-coupled pair is formed from the connection of the fifth transistor 21, the sixth transistor 22, the seventh transistor 23, and the eighth transistor 24. The pair of complementary cross-coupled transistors used as a negative resistance element, which is necessary for frequency generation, to compensate loses of the LC-tank.

The VCO utilizes an LC tuning circuit where the capacitor 16 is a switched capacitor used as a coarse adjustable capacitance element and the capacitor module 17 has two varactor diodes used as a fine adjustable capacitance element to provide continuous or fine adjustable tuning A switch (not shown) is coupled to the capacitor 16 to turn on/off the switched capacitor.

By switching the capacitors 16, the parasitic and stray capacitance exists at switch-off state of the switch. The capacitance between switch-on and switch-off is limited and further narrowing the operation frequency of the VCO. Moreover, the frequency is getting lower the resonance is more away from the operation frequency, then higher loop gain is required to support the oscillation condition. In practical integrated VCO the inductor with low quality factor that dominates the losses of the VCO tank. The gain circuit 2 composed of the fifth transistor 21, the sixth transistor 22, the seventh transistor 23, and the eighth transistor 24, provides high loop gain for oscillation condition. The invention provides high capacitance per unit area, high loop gain and wider tuning range when compared to prior art. Consequently, the circuit of the fifth transistor 21, the sixth transistor 22, the seventh transistor 23, and the eighth transistor 24 has the parasitic and stray capacitance for the loop as switching on/off the these transistors (MMOS/PMOS). Thus the circuit area of switched capacitor is kept small as well as loop gain for oscillation condition is provided.

Specifically, in another embodiment the capacitor 16 and the capacitor module 17 are replaced by the parasitic and stray capacitance existed in the fifth transistor 21, the sixth transistor 22, the seventh transistor 23, and the eighth transistor 24. In FIG. 1, three loop gain circuits 2 equals to three capacitors 20.

Accordingly, by specific ways of connection of the aforementioned elements (i.e., inductors, capacitors, and transistors) and cross-couplings of the aforementioned inductors, the voltage-controlled oscillator of the present invention obtains the advantages to enable it to operate at higher operation frequencies and larger amplitudes but with low voltage and low power consumption.

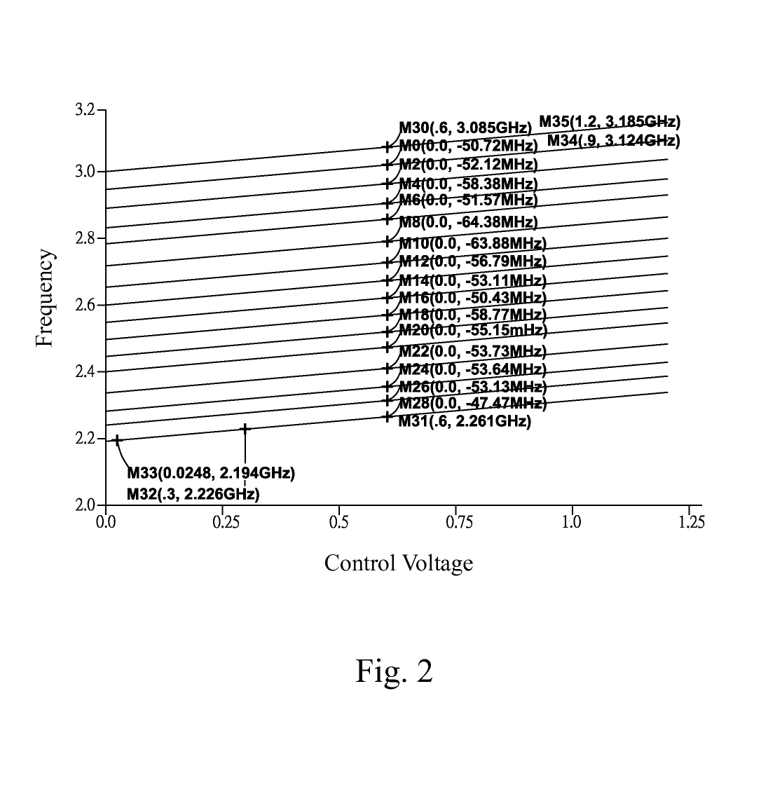

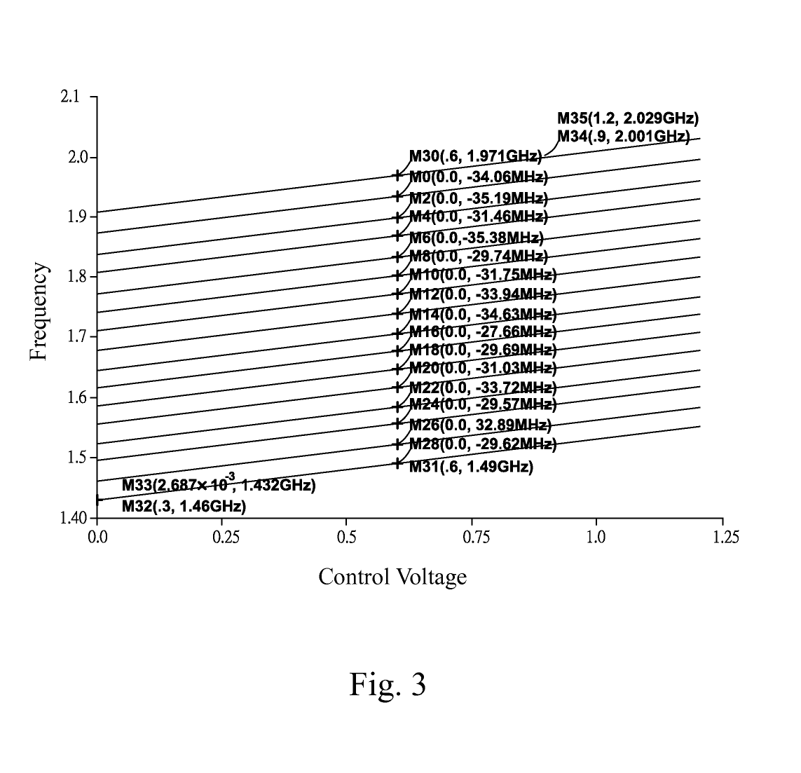

With references to FIG. 2 and FIG. 3, schematic graphs of the oscillation frequency related to control voltage in various switched capacitor and Gm according to the preferred embodiment of the present invention are presented. The graphs show that oscillation frequency related to control voltage in various switched capacitor and Gm. The operational frequency is extended from 3.124 GHz down to 1.46 GHz, thus tuning range expands to 72.6%.

The disclosed circuit provides a new design in fewer electronic components, higher loop gain and low power consumption. The embodiments of the present invention may be practiced in a variety of devices that utilize a voltage controlled oscillator (VCO) and, in particular, a VCO used within a phase locked loop (PLL). However, the invention needs not be limited to a PLL. Furthermore, the examples described herein describe the use of the VCO within a device having wireless communication capability, such as 3G and 4G mobile (or cellular) devices. However, the invention need not be limited to such wireless devices. The invention may be practiced with both wired and wireless devices.

It is to be noted that although the preferred embodiment of the present invention has been described, other modifications, alterations or minor change to the structure should still be within the scope defined in the claims. As those skilled in the art will readily observe that numerous modifications and alterations of the device and method may be made while retaining the teachings of the invention.

What is claimed is:

1. A voltage-controlled oscillator with high loop gain, comprising:
a first transistor, having a source node, a gate node, and a drain node;
a second transistor, having a source node, a gate node, and a drain node, the source node of the second transistor being coupled to the source node of the first transistor, the gate node of the second transistor being coupled to the drain node of the first transistor, and the drain node of the second transistor being coupled to the gate node of the first transistor;
an inductor, having two ends connected with the drain nodes and the gate nodes of the first transistor and the second transistor cross-coupled pair respectively;
a third transistor, having a source node, a gate node, and a drain node, the gate node and the drain node of the third transistor being coupled to the ends of the inductor separately;
a fourth transistor, having a source node, a gate node, and a drain node, the source node of the fourth transistor being coupled to the source node of the third transistor, the gate node of the fourth transistor being coupled to the drain node of the third transistor, and the drain node of the fourth transistor being coupled to the drain node of the third transistor; and
at least one gain circuit, providing a loop gain in the voltage-controlled oscillator, comprising;
a fifth transistor, having a source node, a gate node, and a drain node, the drain node of the fifth transistor being coupled to the inductor;
a sixth transistor, having a source node, a gate node and a drain node, the source node of the sixth transistor being coupled to the source node of the fifth transistor, the gate node of the sixth transistor being coupled to the drain node of the fifth transistor, and the drain node of the sixth transistor being coupled to the gate node of the fifth transistor and the inductor;
a seventh transistor, having a source node, a gate node and a drain node, the drain node of the seventh transistor being coupled to the inductor; and
an eighth transistor, having a source node, a gate node and a drain node, the source node of the eighth transistor being coupled to the source node of the seventh transistor, the gate node of the eighth transistor being coupled to the drain node of the seventh transistor, and the drain node of the eighth transistor being coupled to the gate node of the seventh transistor and the inductor.

2. The voltage-controlled oscillator with high loop gain as claimed in claim 1, wherein the first transistor, the second transistor, the fifth transistor, and the sixth transistor are NMOS transistors.

3. The voltage-controlled oscillator with high loop gain as claimed in claim 2, wherein the third transistor, the fourth transistor, the seventh transistor, and the eighth transistor are PMOS transistors.

4. The voltage-controlled oscillator with high loop gain as claimed in claim 1, further including a capacitor having two electrodes coupled the ends of the inductor separately.

5. The voltage-controlled oscillator with high loop gain as claimed in claim 1, further including a capacitor module having two varactor diodes, whose negative electrodes are coupled with the inductor, and whose positive electrodes are coupled with a voltage-controlled power terminal, which is adapted for externally controllably changing the capacitance of the capacitor module.
